(19) United States
(12) Patent Application Publication
(10) Pub. No.: US 2013/0081845 A1
(43) Pub. Date: Apr. 4, 2013

(54) HOUSING FOR ELECTRONIC COMPONENTS

(71) Applicants: Edward Siahaan, San Francisco, CA (US); Trent Weber, San Francisco, CA (US); Kurt Stiehl, San Jose, CA (US); Bruce Berg, Santa Clara, CA (US)

(72) Inventors: Edward Siahaan, San Francisco, CA (US); Trent Weber, San Francisco, CA (US); Kurt Stiehl, San Jose, CA (US); Bruce Berg, Santa Clara, CA (US)

(21) Appl. No.: 13/250,652

(22) Filed: Sep. 30, 2011

(51) Int. Cl. H05K 5/00; B29C 45/14

(52) U.S. Cl. 174/50; 264/255

(57) ABSTRACT

Improved techniques are disclosed for housing electronic components. A first housing member can be made to have an exterior surface that covers a majority of the housing. The first housing member can be of unitary construction. The first housing member can be seamlessly constructed. The first housing member can be formed in one injection molding. An electrical power conduction pin can extend through an aperture in a cover plate, and can be arranged for mechanically coupling the cover plate with a major interior surface of the first housing member, so as to secure the cover plate to the first housing member.

### BACKGROUND OF THE INVENTION

Casings of various forms are used to house different kinds of products. For example, electronic products need suitable casings to house electronic components for such electronic products.

For portability, product casings should be made to be light weight. Market studies suggest strong consumer preference for light weight products over heavier products in the marketplace.

However, there is also a need for products and their casings to be rugged. While attributes such as strength and ruggedness of casings may be increased by using more materials, this can make them thicker or heavier, and therefore less desirable to consumers, for the reasons just discussed.

Strength requirements for portable product casings can be particularly demanding, since portable products tend to have a higher likelihood of being accidently dropped. When portable products are dropped on hard surfaces, the shock of the drop can induce substantial mechanical stress on product casings. If product casings are seamed together, sufficient mechanical stress from extreme shock of a severe drop event can cause seams of the product casings to fail.

Thus, there is a need for improved approaches to housings for electronic components.

### SUMMARY

Improved techniques are disclosed for housing electronic components. A first housing member can be made to have an exterior surface that covers a majority of the housing. The first housing member can be of unitary construction. The first housing member can be seamlessly constructed. The first housing member can be formed in one injection molding. An electrical power conduction pin can extend through an aperture in a cover plate, and can be arranged for mechanically coupling the cover plate with the major interior surface of the first housing member, so as to secure the cover plate to the first housing member. Several embodiments of the invention are discussed below.

The invention can be implemented in numerous ways, including as a method, system, device, or apparatus. Several embodiments of the invention are discussed below.

As a housing for electronic components, one embodiment can, for example, included at least a first housing member having a major interior surface that defines an interior cavity for receiving the electronic components. A major aperture of the first housing member can extend from the interior cavity through the first housing member to an exterior surface of the first housing member. A cover plate can engage the major aperture of the first housing member. An electrical power conduction pin can extend through an aperture in the cover plate and can be arranged for mechanically coupling the cover plate with the major interior surface of the first housing member, so as to secure the cover plate to the first housing member.

As a method for assembling a housing for electronic components, one embodiment can, for example, include at least: providing a first housing member having a major interior surface that defines an interior cavity for receiving the electronic components; providing a major aperture of the first housing member, extending through the first housing member from an exterior surface of the first housing to the interior cavity of the first housing member; providing a cover plate for engaging the major aperture of the first housing member; mechanically coupling a threaded insert member with the interior surface of the first housing member; extending a threaded extremity of an electrical power conduction pin through an aperture in the cover plate; and engaging the threaded insert member with a threaded extremity of the electrical power conduction pin for securing the cover plate to the first housing member.

As a method of molding a housing one embodiment can, for example, include at least: providing an inner core mold assembly having a plurality of selectively moveable components, wherein the inner core mold assembly has an outer surface; molding a major interior surface that defines an interior cavity of the housing over a portion of the outer surface of the inner core mold assembly; and molding a major aperture of the housing over an extremity of the inner core mold assembly, so that the major aperture extends through the housing from the interior cavity of the housing, wherein molding the major interior surface sufficiently encompasses the interior cavity for the housing substantially occluding viewing of the major interior surface through the major aperture.

Other aspects and advantages of the invention will become apparent from the following detailed description taken in conjunction with the accompanying drawings which illustrate, by way of example, the principles of the invention.

### BRIEF DESCRIPTION OF THE DRAWINGS

The invention will be readily understood by the following detailed description in conjunction with the accompanying drawings, wherein like reference numerals designate like structural elements, and in which:

FIGS. 1A-1E show various views of a housing for electronic components, according to one embodiment.

FIG. 2 is a flow diagram of a process for assembling a housing for electronic components.

FIGS. 3A-3C are simplified cross sectional views of molding a first housing member.

FIGS. 4A-4J show disassembly of a core mold assembly.

FIGS. 5A and 5B show rotated views of a cover plate.

FIGS. 6A and 6B show a flow diagram of a process for molding a housing.

FIGS. 7A and 7B are simplified cut-away views of alternative molding/demolding of first housing member.

### DETAILED DESCRIPTION OF EMBODIMENTS OF THE INVENTION

Improved techniques are disclosed for housing electronic components. A first housing member can be made to have an exterior surface that covers a majority of the housing. The first housing member can be of unitary construction. The first housing member can be seamlessly constructed. The first housing member can be formed in one injection molding. An electrical power conduction pin can extend through an aperture in a cover plate, and can be arranged for mechanically coupling the cover plate with the major interior surface of the first housing member, so as to secure the cover plate to the first housing member. Several embodiments of the invention are discussed below.

The following detailed description is illustrative only, and is not intended to be in any way limiting. Other embodiments will readily suggest themselves to skilled persons having the benefit of this disclosure. Reference will now be made in detail to implementations as illustrated in the accompanying drawings. The same reference indicators will generally be used throughout the drawings and the following detailed description to refer to the same or like parts. It should be appreciated that the drawings are generally not drawn to scale, and at least some features of the drawings have been exaggerated for ease of illustration.

In the interest of clarity, not all of the routine features of the implementations described herein are shown and described. It will, of course, be appreciated that in the development/design of any such actual implementation, numerous implementation-specific decisions must be made in order to achieve the developer's/designer's specific goals, such as compliance with application and business related constraints, and that these specific goals will vary from one implementation to another and from one developer/designer to another. Moreover, it will be appreciated that such a development/design effort might be complex and time-consuming, but would nevertheless be a routine undertaking of engineering for those of ordinary skill in the art having the benefit of this disclosure.

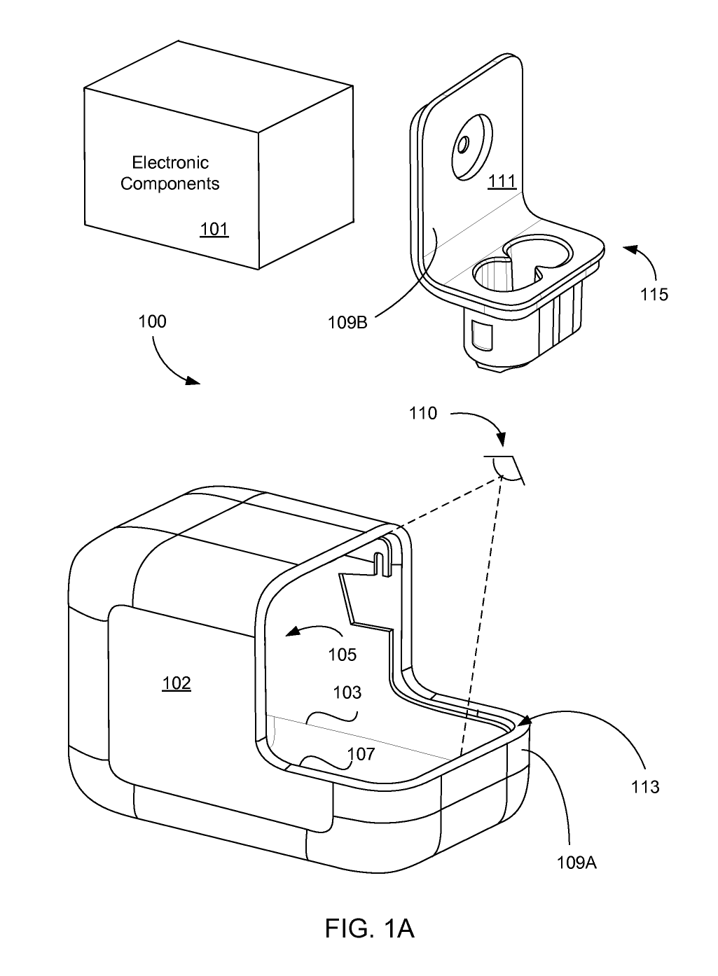

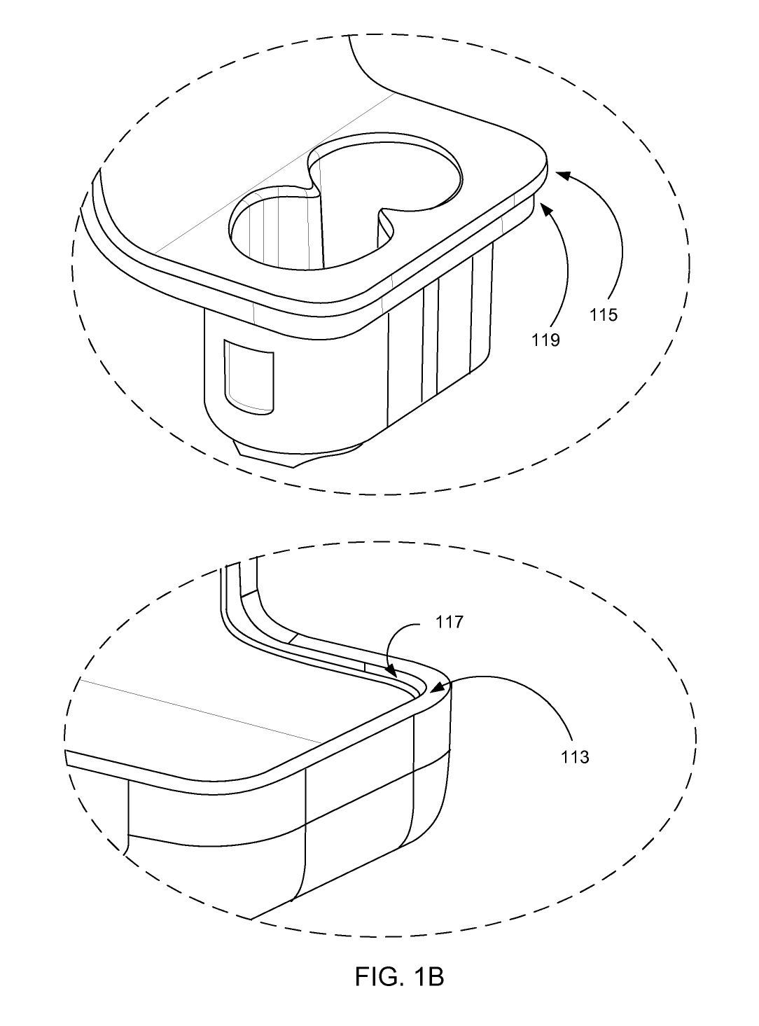

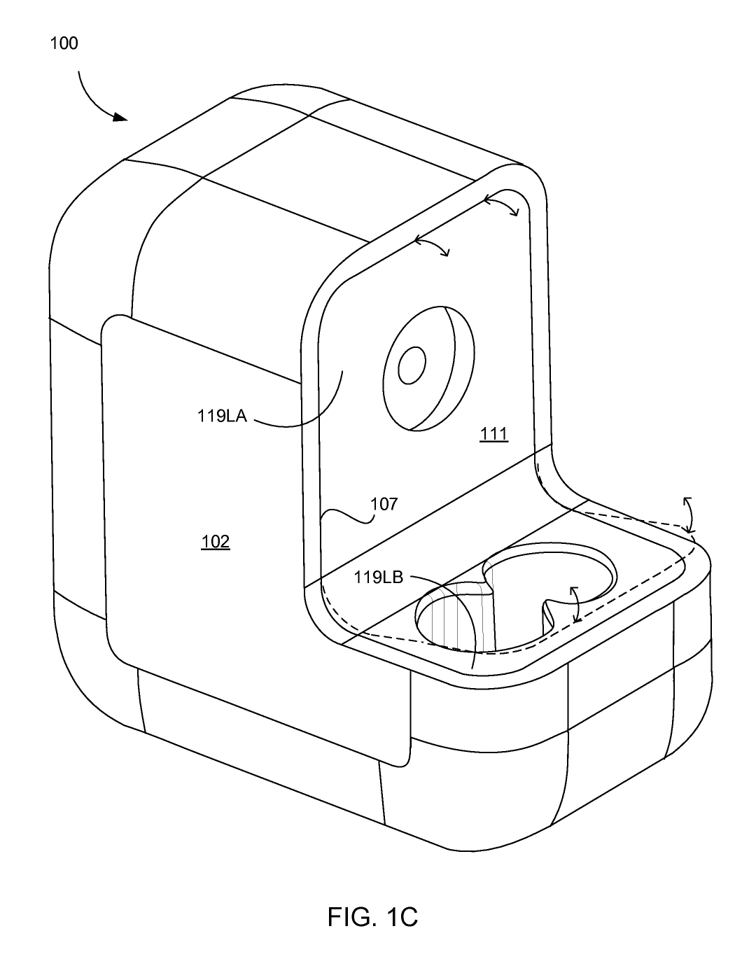

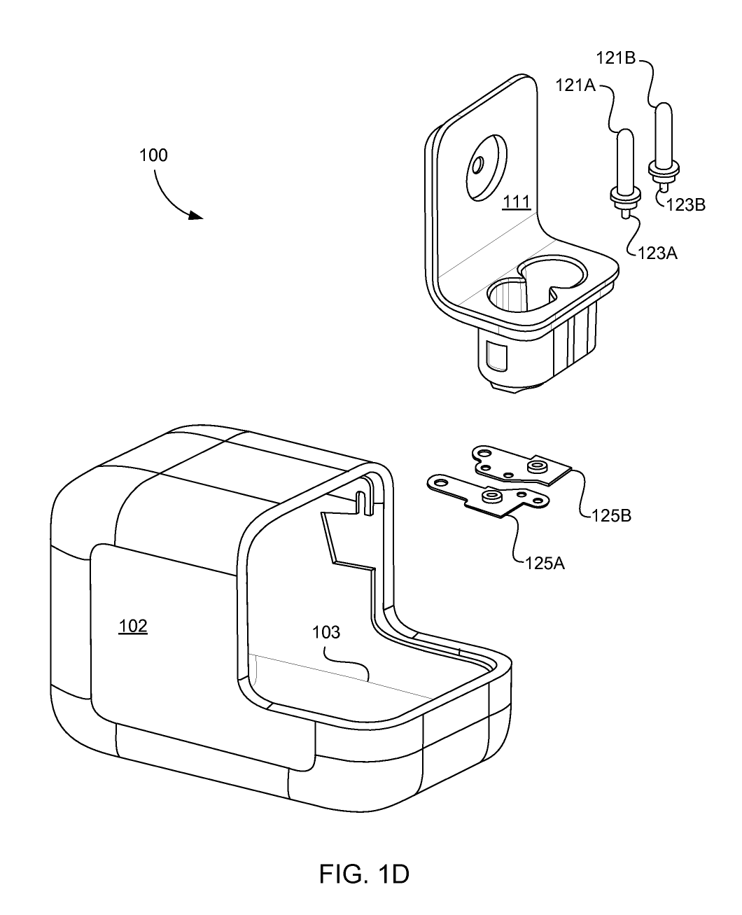

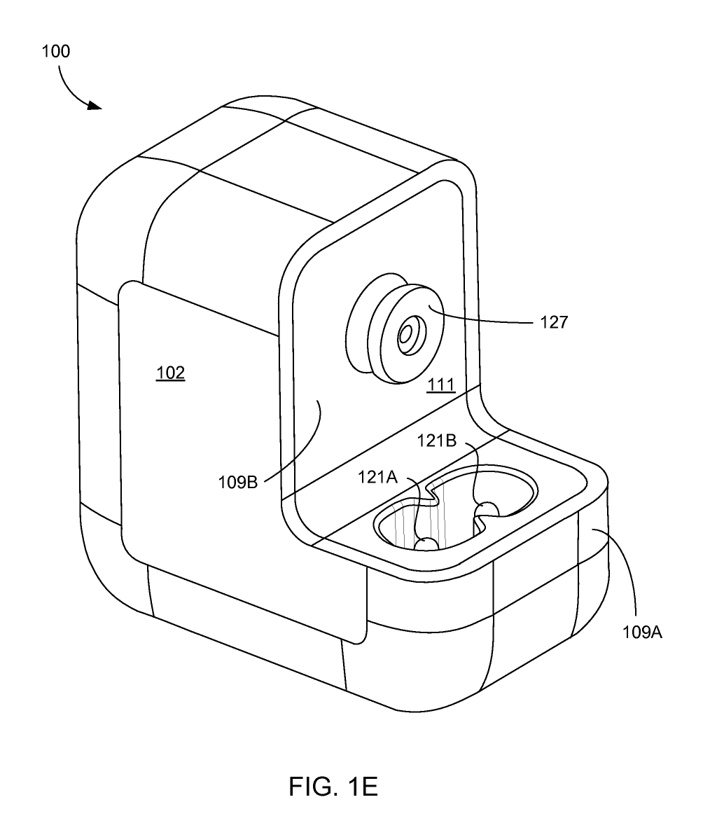

Embodiments of the invention are discussed below with reference to FIGS. 1-7B. However, those skilled in the art will readily appreciate that the detailed description given herein with respect to these figures is for explanatory purposes, as the invention extends beyond these limited embodiments.

FIG. 1A shows housing 100 for electronic components 101. The housing may comprise a first housing member 102. The first housing member 102 may have a major interior surface 103 that defines an interior cavity 105 for receiving the electronic components 101. The first housing member may have a major aperture 107 extending from the interior cavity 105 through the first housing member 102 to an exterior surface 109A of the first housing member 102.

First housing member 102 can be of unitary construction. First housing member 102 can be seamlessly constructed. First housing member 102 can be formed in one injection molding.

The exterior surface 109A of the first housing member 102 can cover a majority of the housing 100. Cover plate 111 can have an exterior surface 109B, which can substantially cover a minority remainder of the housing 100.

For purposes of illustration in FIG. 1A, a notional eye 110 is shown having a view of a portion of the major interior surface 103 of the first housing member 102 through the major aperture 107, wherein the first housing member 102 substantially occludes full view of the major interior surface 103 of the first housing member 102 through the major aperture 107. In other words, substantial portions of the major interior surface 103 of the first housing member 102 are not viewable through the major aperture 107, because the view is occluded by the first housing member 102. The first housing member 102 sufficiently encompasses the interior cavity 105 for substantially occluding viewing of the major interior surface 103 through the major aperture 107.

Housing 100 may further comprise a cover plate 111 for engaging the major aperture 107 of the first housing member 102. The cover plate 111 may have a substantially L-shaped cross section. Similarly, the major aperture 107 of the first housing member 102 may have a substantially L-shaped cross section.

The major aperture 107 of the first housing member 102 can have an interior perimeter 113 adjacent to the exterior surface 109A of the first housing member 102. The cover plate 111 can have an exterior perimeter 115. When the first housing member is assembled with the cover plate 111, at least a portion of the exterior perimeter 115 of the cover plate 111 can engage at least a portion of the interior perimeter of the 113 major aperture of the first housing member.

FIG. 1B shows magnified detailed partial views of the interior perimeter 113 of the major aperture of the first housing member. The interior perimeter 113 of the major aperture 107 has a reflex edge region 117 for engaging the cover plate 111. For the reflex edge region 117, an inner dihedral angle subtended by two incident facets is greater than 180 degrees.

The exterior perimeter 115 of the cover plate is also shown magnified detailed partial view in FIG. 1B. The cover plate 111 can have a mating reflex edge region 119 for engaging the reflex edge region 117 of the interior perimeter 113 of the major aperture.

The cover plate 111 may be substantially resilient. In FIG. 1C, flex of the cover plate is depicted in dashed line. Flexed insertion of the cover plate 111 into the major aperture 107 of the first housing member 102 can exert a restoring force of the cover plate 111 against the major aperture 107, for retaining the cover plate 111 within the major aperture 107 of the first housing member 102. Notional arc arrows are shown in FIG. 1C to depict flex/restoring forces.

The cover plate 111 can have a substantially L-shaped cross section defining substantially orthogonal leg portions 119LA, 119LB. Upon flexed insertion of the cover plate 111 into the major aperture 107 of the first housing member 102, the substantially orthogonal leg portions 119LA, 119LB can be flexed towards each other.

As shown in exploded view in FIG. 1D, and in assembled view in FIG. 1E, housing 100 may further comprise electrical power conduction pins 121A, 121B. Electrical power conduction pins 121A, 121B may extend through minor apertures in the cover plate 111. Electrical power conduction pins 121A, 121B may be arranged for mechanically coupling the cover plate 111 with the major interior surface 103 of the first housing member 102, so as to secure the cover plate 111 to the first housing member 102.

Electrical power conduction pins 121A, 121B may have threaded extremities 123A, 123B. Housing 100 may further comprise threaded insert members 125A, 125B for receiving the threaded extremities 123A, 123B of the electrical power conduction pins 121A, 121B. The threaded insert members 125A, 125B can be mechanically coupled with the major interior surface 103 of the first housing member 102.

First housing member 102 may comprises injection molded plastic. The threaded insert members 125A, 125B may be over-molded with the major interior surface 103 of the first housing member for retaining the threaded insert members 125A, 125B. Alternatively or additionally, the threaded insert members 125A, 125B may be heat staked to the major interior surface 103 of the first housing member 102 for retaining the threaded insert members 125A, 125B.

The threaded insert members 125A, 125B may be glued to the major interior surface 103 of the first housing member 102 for retaining the threaded insert members 125A, 125B. The threaded insert members 125A, 125B may be ultrasonically welded to the major interior surface 103 of the first housing member 102 for retaining the threaded insert members 125A, 125B.

As shown in assembled view in FIG. 1E, the first housing member can be made so that the exterior surface 109A covers the majority of the housing 100. The exterior surface 109B of cover plate 111 can substantially cover the minority remainder of the housing 100. Housing 100 may further comprise an external retention nut 127 coupled with the cover plate 111.

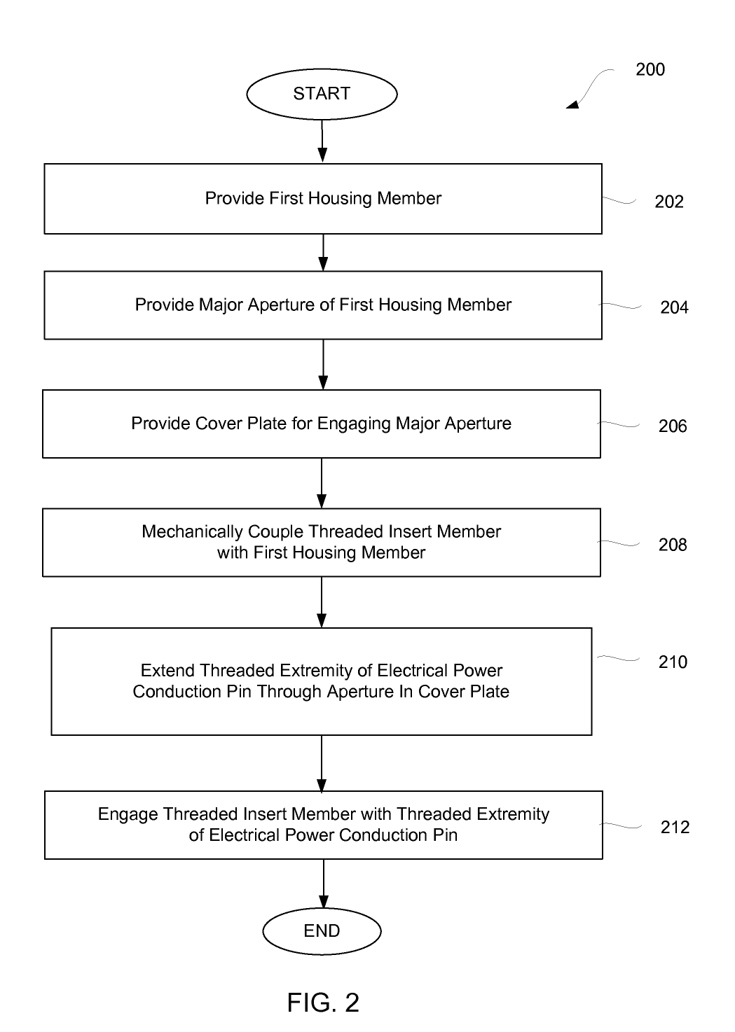

FIG. 2 is a flow diagram of a process 200 for assembling a housing for electronic components. In accordance with the process 200 shown in FIG. 2, the process may begin with providing 202 a first housing member having a major interior surface that defines an interior cavity for receiving the electronic components.

Process 200 can continue with providing 204 a major aperture of the first housing member, extending through the first housing member from an exterior surface of the first housing to the interior cavity of the first housing member. The first housing member can be made to have an exterior surface that covers a majority of the housing. The first housing member can sufficiently encompass the interior cavity for substantially occluding viewing of the major interior surface through the major aperture.

Process 200 can continue with providing 206 a cover plate for engaging the major aperture of the first housing member. The cover plate can have an exterior surface, which can substantially cover a minority remainder of the housing.

Process 200 can continue with mechanically coupling 208 a threaded insert member with the interior surface of the first housing member. Mechanically coupling 208 the threaded insert member with the interior surface of the first housing member may comprise overmolding the threaded insert member with the interior surface of the first housing member. Mechanically coupling 208 the threaded insert member with the interior surface of the first housing member may comprise heat staking the threaded insert member to the interior surface of the first housing member. Mechanically coupling 208 the threaded insert member with the interior surface of the first housing member may comprise gluing the threaded insert member to the interior surface of the first housing member. Mechanically coupling the threaded insert member with the interior surface of the first housing member may comprise ultrasonically welding the threaded insert member to the interior surface of the first housing member.

Process 200 can continue with extending 210 a threaded extremity of an electrical power conduction pin through an aperture in the cover plate. Process 200 can continue with engaging 212 the threaded insert member with a threaded extremity of the electrical power conduction pin for securing the cover plate to the first housing member. Following the engaging block 212, the process 200 shown in FIG. 2 can end.

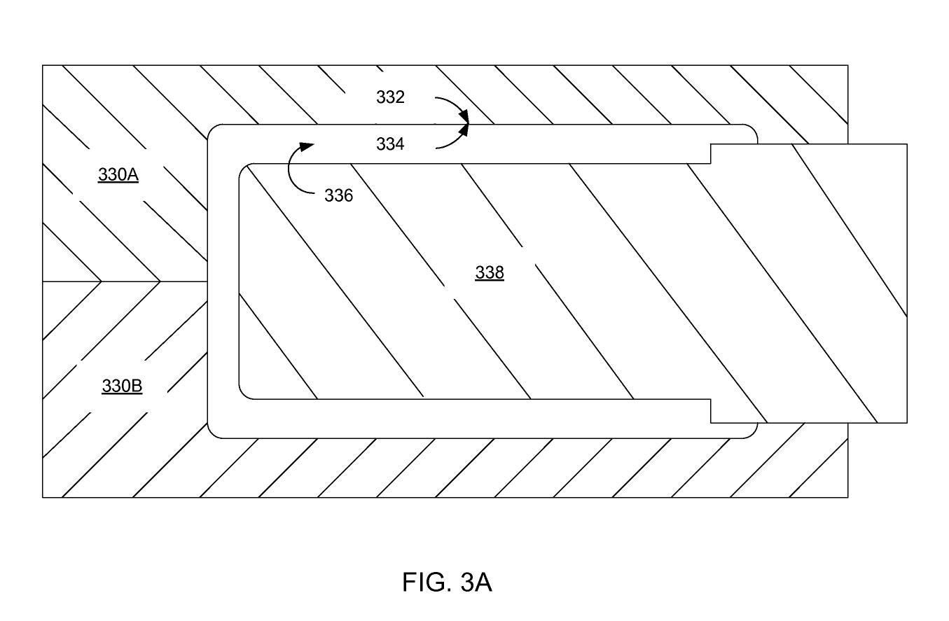

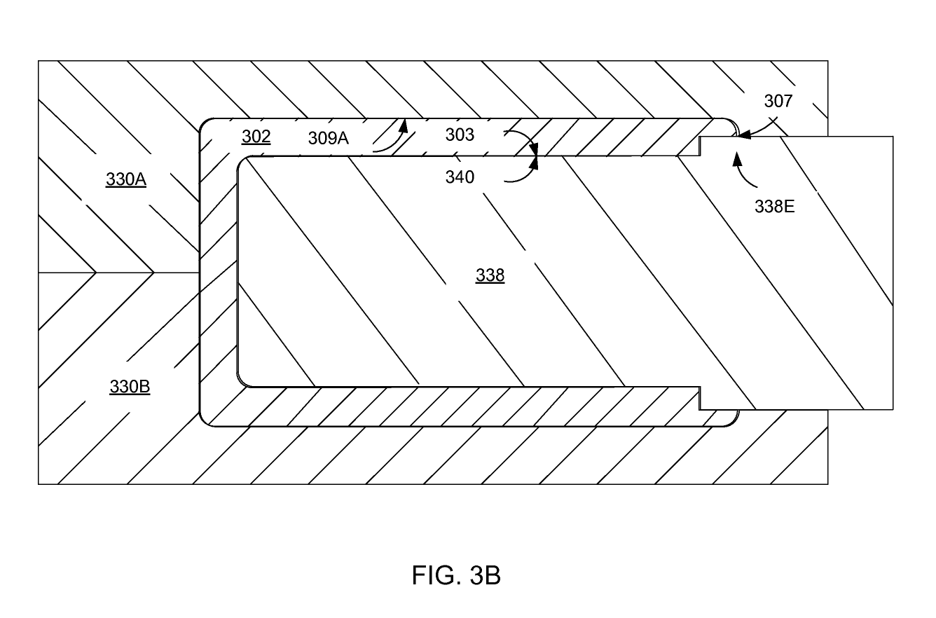

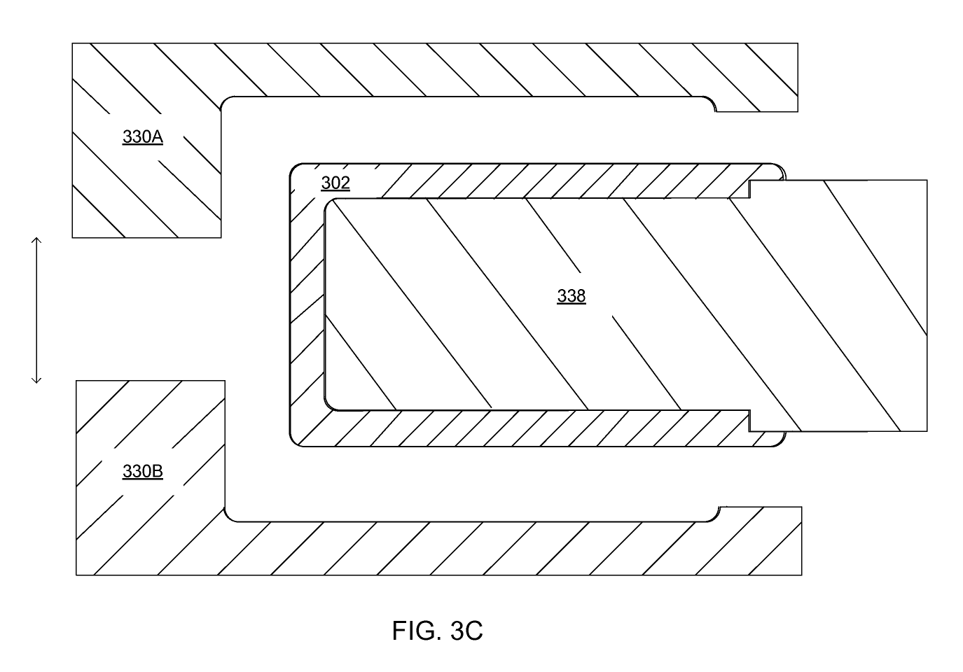

FIGS. 3A-3C are simplified cross sectional views of molding a first housing member. FIG. 3A shows first and second mated plates 330A, 330B having an inner surface 332 for defining an outer surface 334 of a mold cavity 336.

An inner core mold assembly 338 can be disposed within the mold cavity 336. As discussed in greater detail subsequently herein, the inner core mold assembly 338 can have a plurality of selectively moveable components, for disassembling the inner core mold assembly during demolding.

As shown in FIG. 3B, plastic material can be injected into the mold cavity for molding first housing member 302. As shown in cross sectional view in FIG. 3B, the inner core mold assembly 338 has an outer surface 340. A major interior surface 303 that defines an interior cavity of the first housing member can be molded over a portion of the outer surface 340 of the inner core mold assembly 338.

A major aperture 307 of the first housing member can be molded over an extremity 338E of the inner core mold assembly 338, so that the major aperture 307 extends through the first housing member 302 from the interior cavity of the first housing member 302.

An exterior surface 309A of first housing 302 can be formed by molding the exterior surface 309A of the first housing member to the outer surface of the mold cavity.

As shown in FIG. 3C the first housing member 302 can be demolded from the first and second mated plates 330A, 330B by separating the first and second mated plates 330A, 330B along a parting direction, as illustrated in FIG. 3C using notional bidirectional arrows.

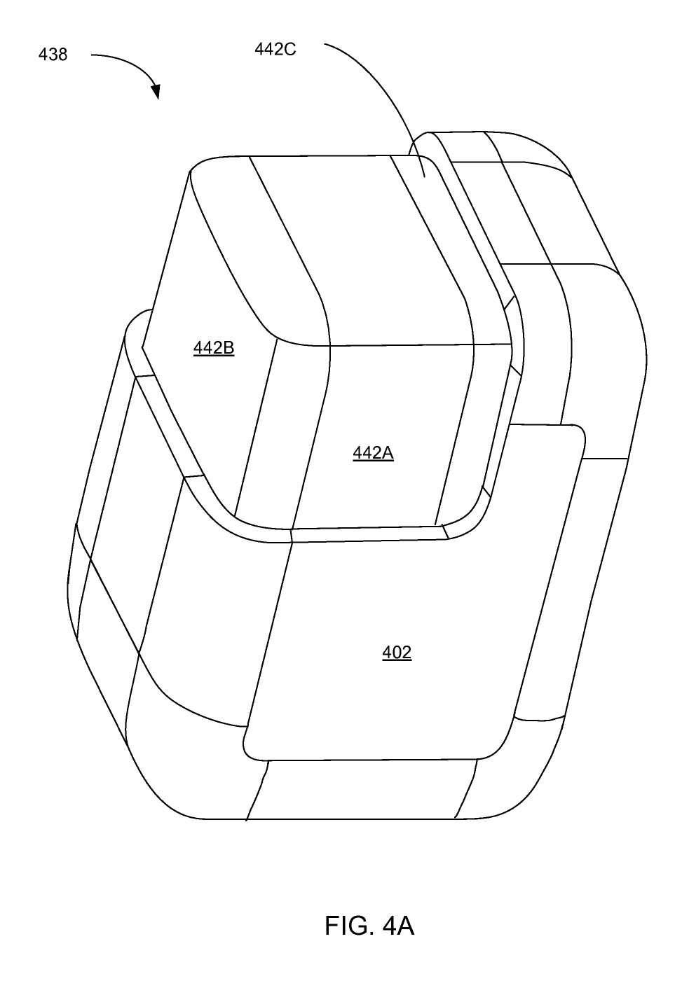

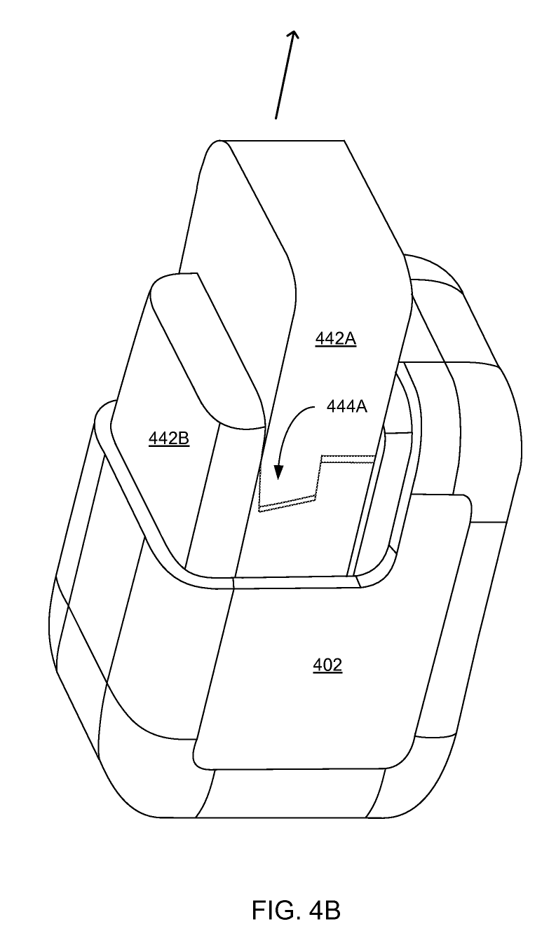

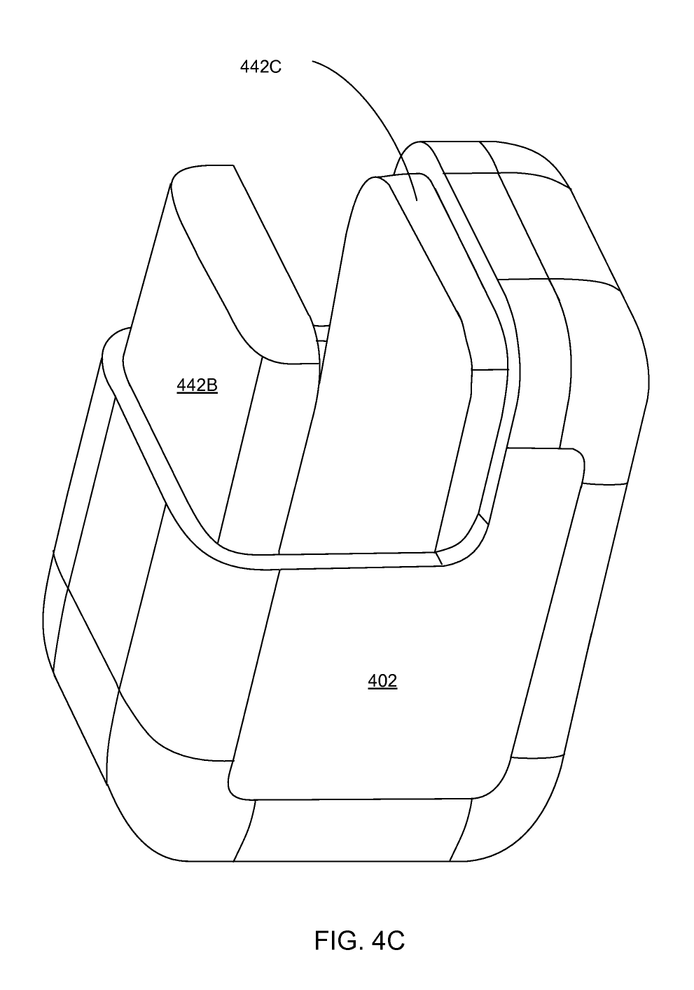

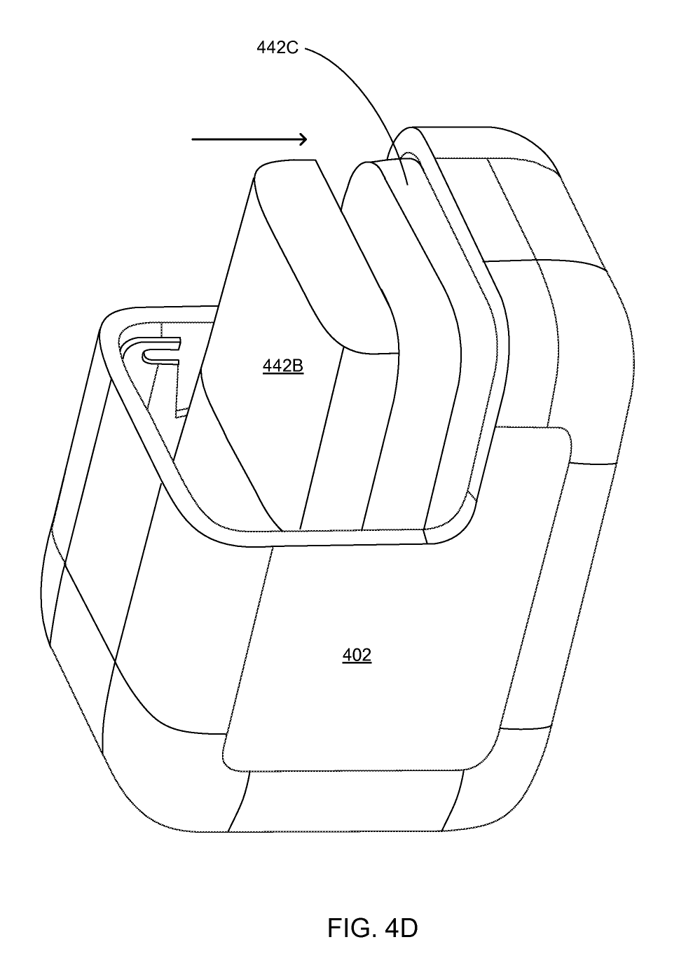

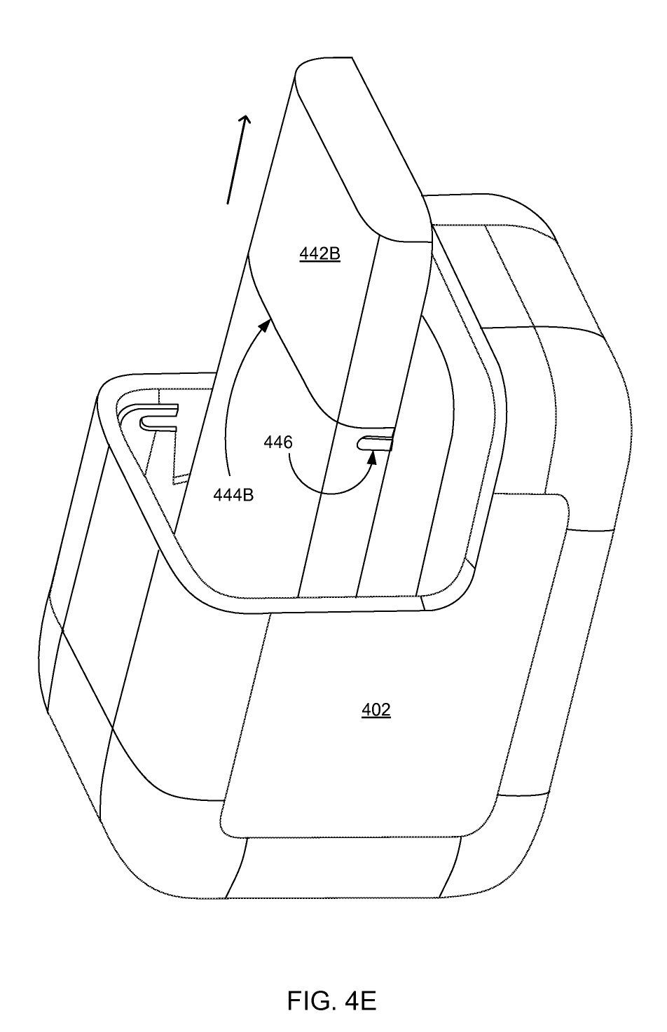

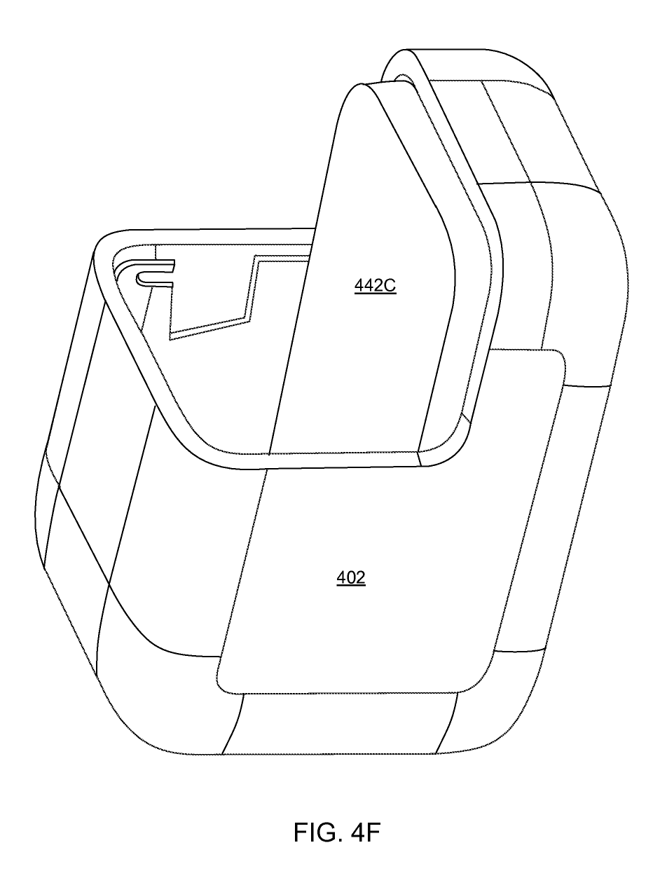

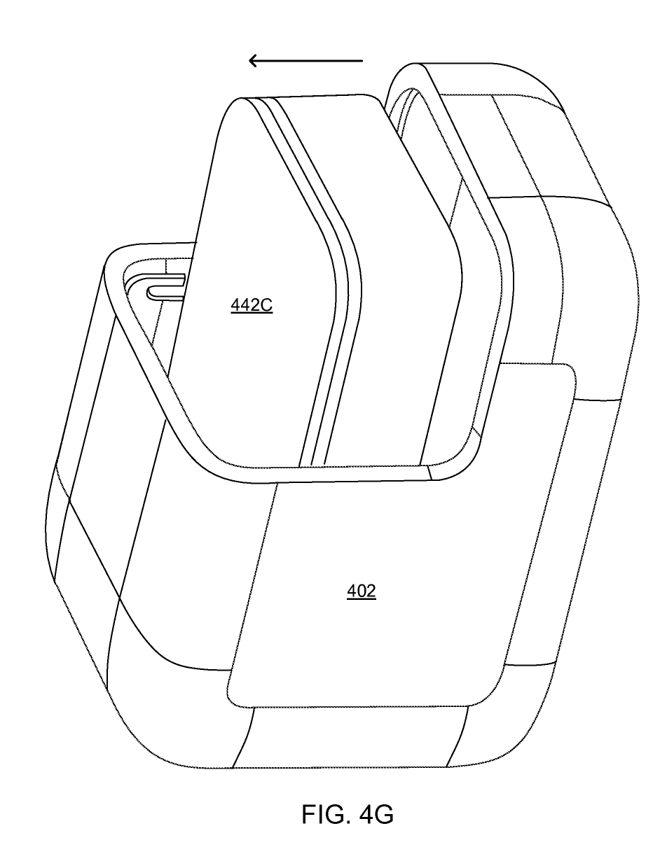

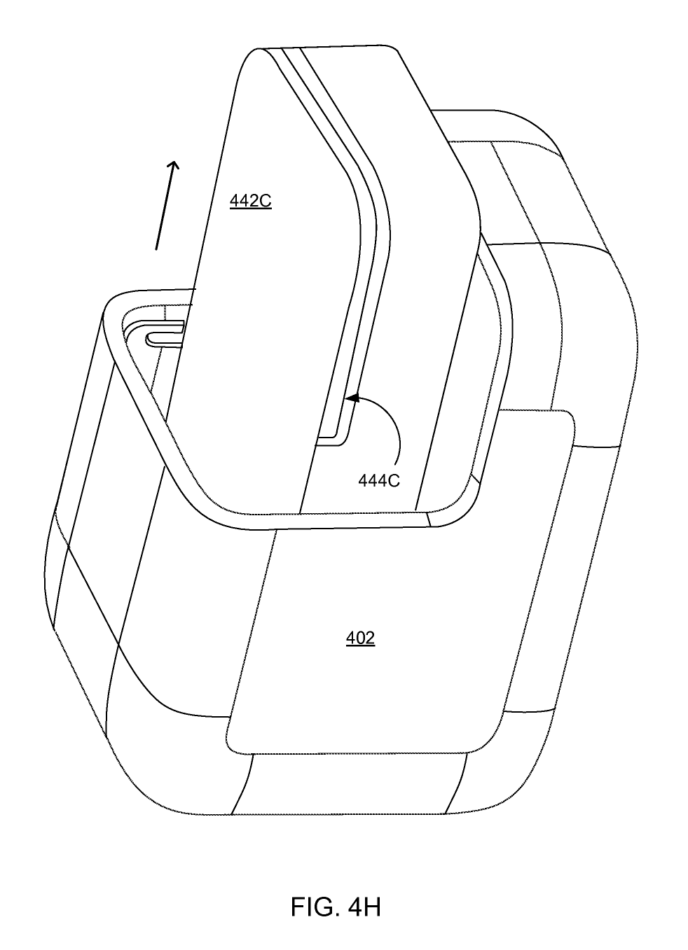

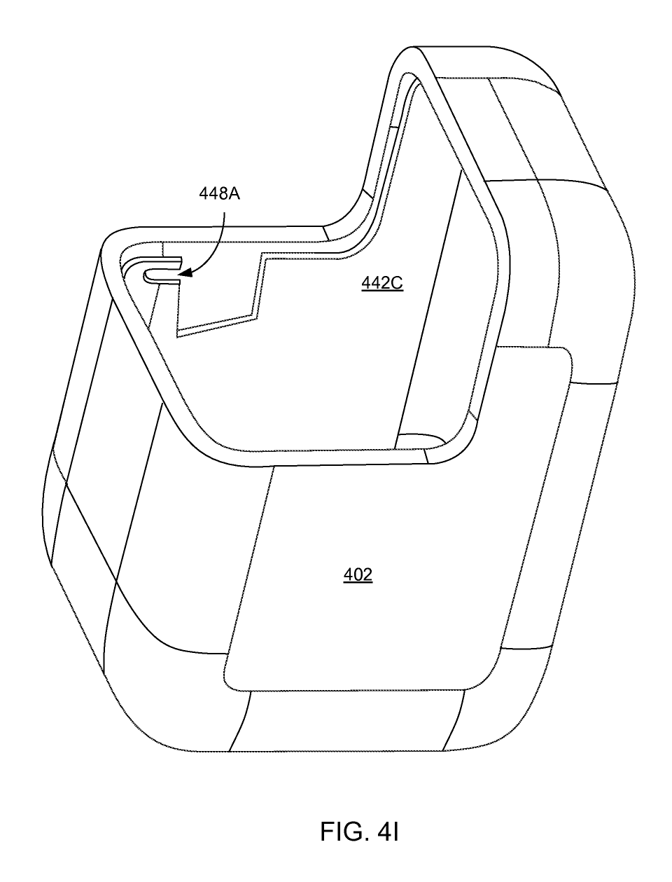

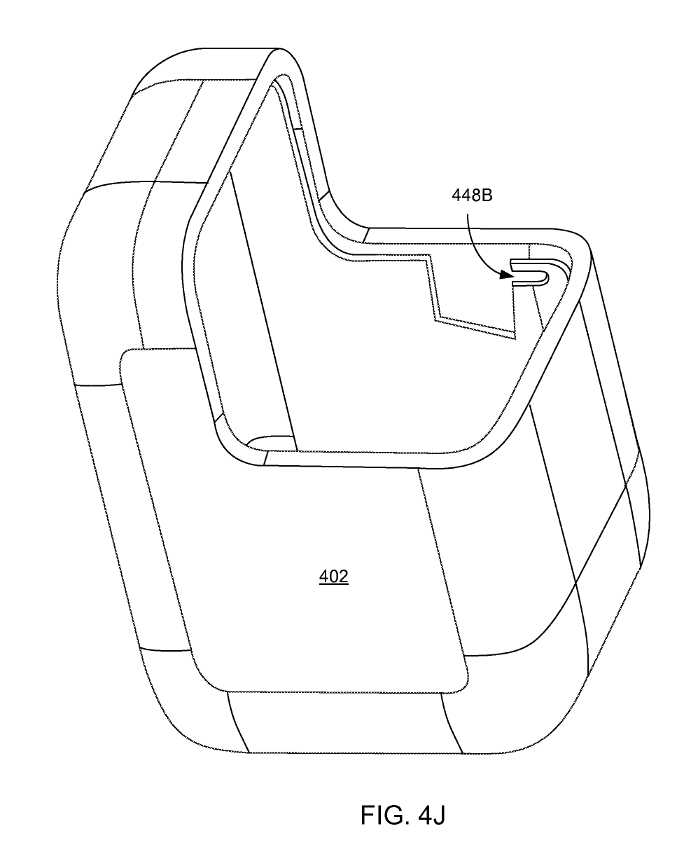

FIGS. 4A-4J show disassembly of inner core mold assembly 438. Inner core mold assembly 438 can have a plurality of selectively moveable components 442A, 442B, 442C for disassembling the inner core mold assembly 438 during demolding. The plurality of selectively moveable components 442A, 442B, 442C can be slidably disassembled, for disassembling the inner core mold assembly 438. As shown in FIGS. 4A-4J, each of the selectively moveable components 442A, 442B, 442C of the inner core mold assembly can be sequentially removed from the interior cavity, through the major aperture of the first housing member 402.

For example, as particularly shown in FIG. 4B, a first component 442A of the inner core mold assembly can slide outwardly from the interior cavity, through the major aperture of the first housing member 402. A notional arrow head shows direction of the first component 442A of the inner core mold assembly sliding outwardly from the interior cavity, through the major aperture of the first housing member 402. In FIG. 4B a first reflex edge mold feature 444A of the inner core mold assembly is shown. The first reflex edge mold feature 444A can mold a portion of the reflex edge region of the first housing member, as discussed previously herein. The first component 442A of the inner core mold assembly can be removed from the interior cavity, through the major aperture of the first housing member 402.

FIG. 4C shows the first housing member 402 after the first component of the inner core mold assembly has been removed from the interior cavity.

FIG. 4D shows lateral sliding of a second component 442B of the inner core mold assembly. A notional arrow head in FIG. 4C shows direction of lateral sliding of the second component 442B towards a center of the cavity of the first housing member 402.

FIG. 4E shows the second component 442B of the inner core mold assembly sliding outwardly from the interior cavity, through the major aperture of the first housing member 402. A notional arrow head shows direction of the second component 442B of the inner core mold assembly sliding outwardly from the interior cavity, through the major aperture of the first housing member 402.

In FIG. 4E a second reflex edge mold feature 444B of the inner core mold assembly is shown. The second reflex edge mold feature 444B can mold another portion of the reflex edge region of the first housing member, as discussed previously herein.

In FIG. 4E an interior surface pocket mold feature 446 of the inner core mold assembly is shown. The interior surface pocket mold feature 446 can mold an interior surface pocket feature of the first housing member 402. The interior surface pocket feature of the first housing member 402 will be discussed in greater detail subsequently herein.

The second component 442B of the inner core mold assembly can be removed from the interior cavity, through the major aperture of the first housing member 402.

FIG. 4F shows the first housing member 402 after the first component of the inner core mold assembly has been removed from the interior cavity.

FIG. 4G shows lateral sliding of a third component 442C of the inner core mold assembly. A notional arrow head in FIG. 4G shows direction of lateral sliding of the third component 442C towards a center of the cavity of the first housing member 402.

FIG. 4H shows the third component 442C of the inner core mold assembly sliding outwardly from the interior cavity, through the major aperture of the first housing member 402. A notional arrow head shows direction of the third component 442C of the inner core mold assembly sliding outwardly from the interior cavity, through the major aperture of the first housing member 402.

In FIG. 4H a third reflex edge mold feature 444C of the inner core mold assembly is shown. The third reflex edge mold feature 444C can mold yet another portion of the reflex edge region of the first housing member, as discussed previously herein.

The third component 442C of the inner core mold assembly can be removed from the interior cavity, through the major aperture of the first housing member 402.

FIGS. 4I and 4J show the first housing member 402 after the third component of the inner core mold assembly has been removed from the interior cavity. FIGS. 4I and 4J show rotated views of the first housing member 402. In FIGS. 4I and 4J show a pair interior surface pocket features 448A, 448B of the first housing member 402

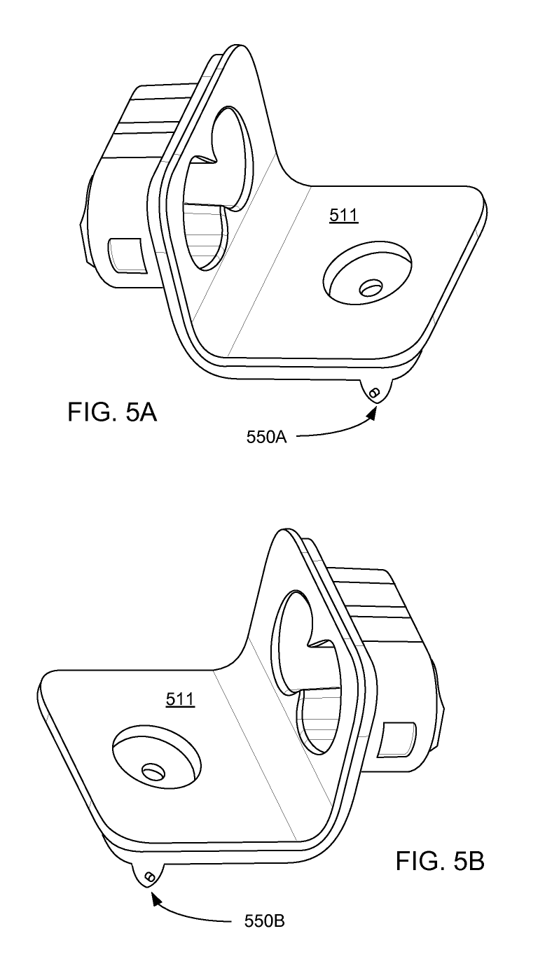

FIGS. 5A and 5B show rotated views of cover plate 511. FIGS. 5A and 5B particularly show a pair of post features 550A and 550B, for engaging the pair interior surface pocket features 448A, 448B of the first housing member 402, as just discussed with respect to FIGS. 4I and 4J.

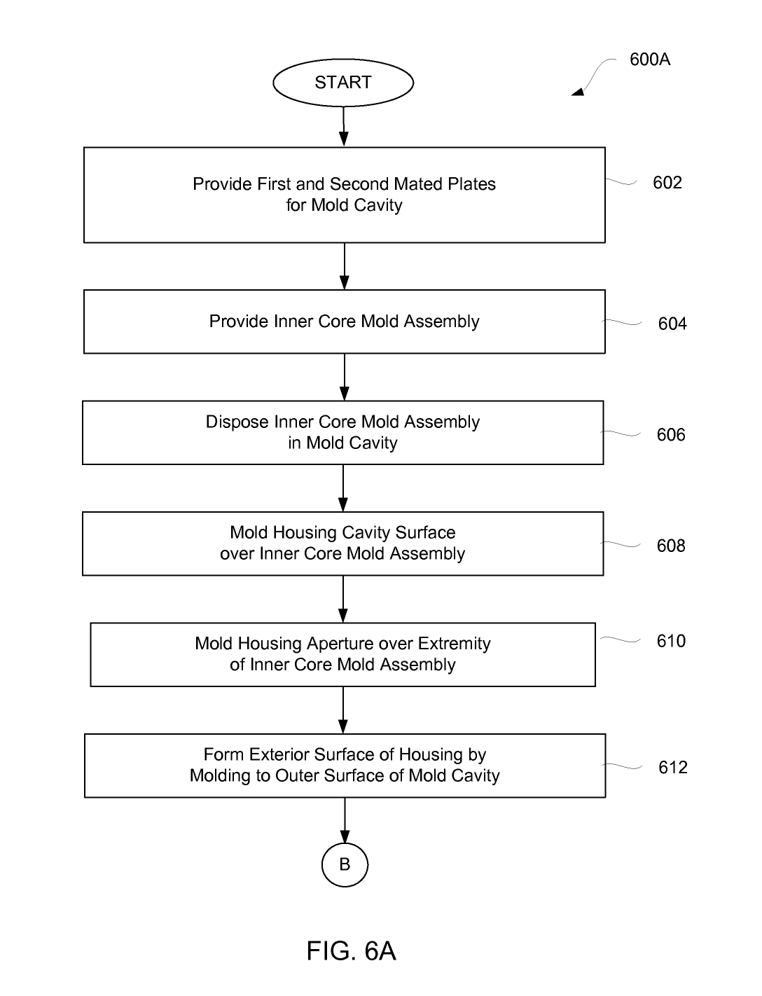

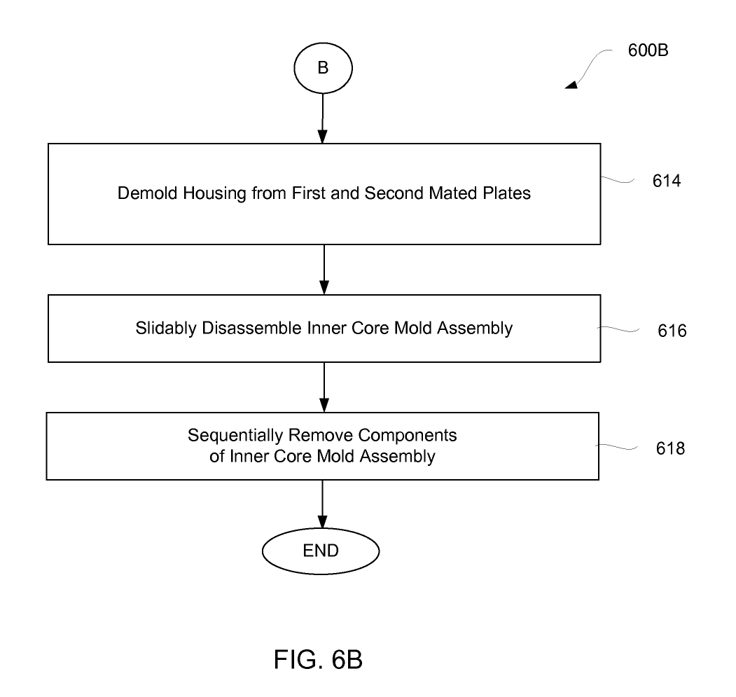

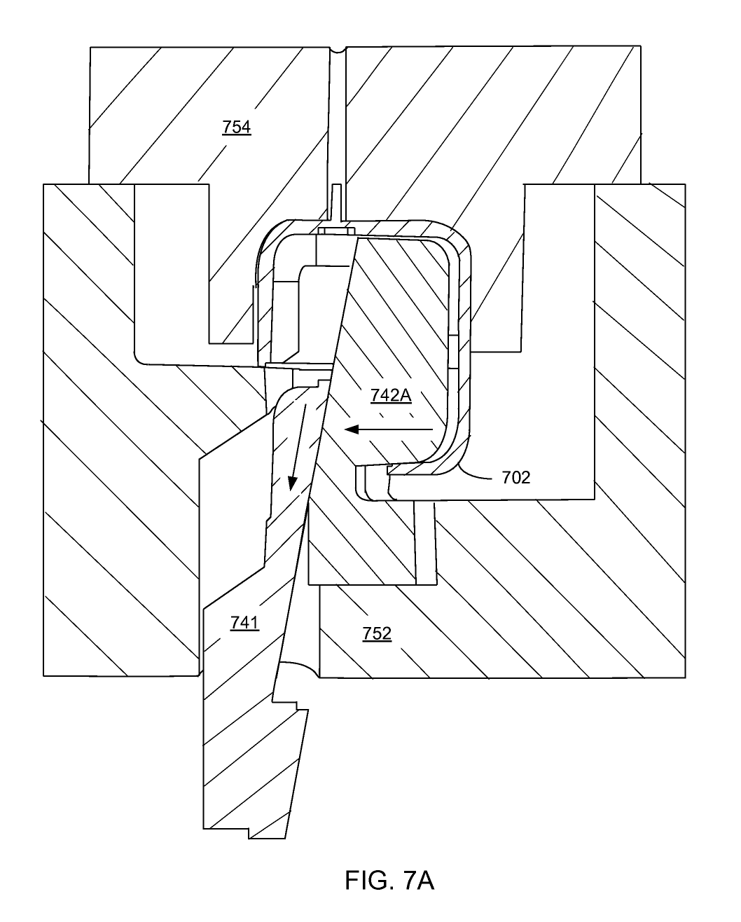

FIGS. 6A and 6B show a flow diagram of a process 600A, 600B for molding a housing. An initial part of the process 600A is shown in FIG. 6A. A continuing part of the process 600B is shown in FIG. 6B.

In accordance with an initial part of the process 600A shown in FIG. 6A, the initial part of the process may begin with providing 602 first and second mated plates having an inner surface for defining an outer surface of a mold cavity. The process 600A can continue with providing 604 an inner core mold assembly having a plurality of selectively moveable components, wherein the inner core mold assembly has an outer surface

The process 600A can continue with disposing 606 the inner core mold assembly with the mold cavity. The process 600A can continue with molding 608 a major interior surface that defines a interior cavity of the housing over a portion of the outer surface of the inner core mold assembly. Molding 608 the major interior surface and can include molding the interior surface to sufficiently encompasses the interior cavity so that the housing substantially occludes viewing of the major interior surface through the major aperture.

The process 600A can continue with molding 610 a major aperture of the housing over an extremity of the inner core mold assembly, so that the major aperture extends through the housing from the interior cavity of the housing. The process 600A can continue with forming 612 an exterior surface of housing by molding the exterior surface of the housing to the outer surface of the mold cavity.

In accordance with the continuing part of the process 600B shown in FIG. 6B, the process 600B can continue with demolding 614 the housing from the first and second mated plates by separating the first and second mated plates along a parting direction. The process 600B can continue with slidably disassembling 616 the inner core mold assembly. The process 600B can continue with sequentially removing 618 each of the plurality of selectively moveable components of the inner core mold assembly from the interior cavity, through the major aperture of the housing. After the sequentially removing block 618, the process 600B can end.

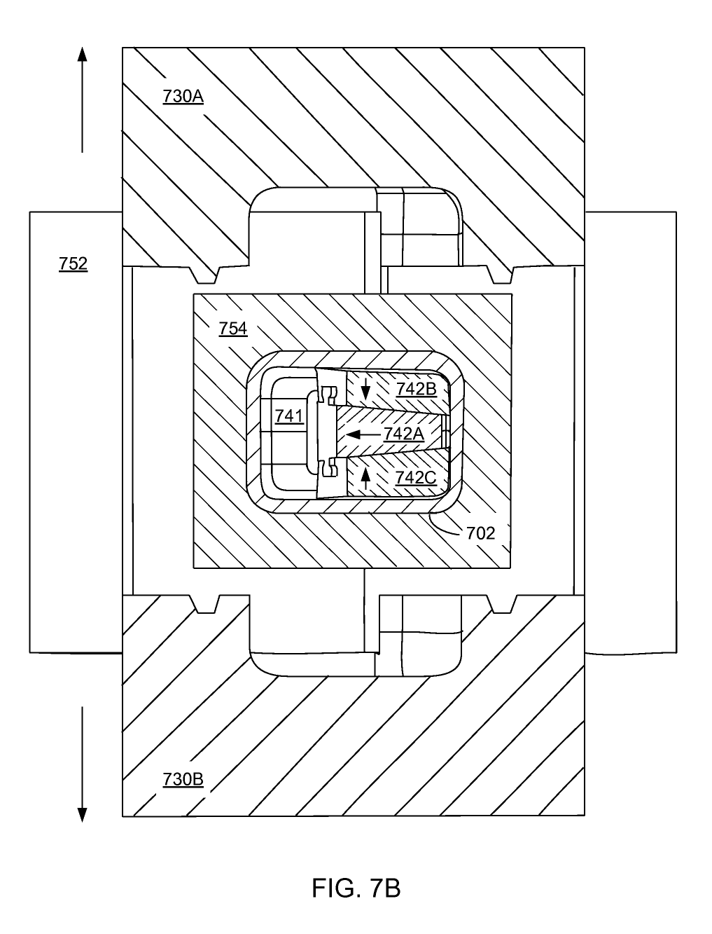

FIGS. 7A and 7B are simplified cut-away views of alternative molding/demolding of first housing member 702. Additional molding fixtures 752, 754 are shown in FIGS. 7A and 7B. The inner core mold assembly can have a plurality of selectively moveable components 741, 742A, 742B, 742C for disassembling the inner core mold assembly during demolding. The plurality of selectively moveable components 741, 742A, 742B, 742C can be slidably disassembled, for disassembling the inner core mold assembly.

Each of the selectively moveable components 741, 742A, 742B, 742C of the inner core mold assembly can be sequentially removed from the interior cavity, through the major aperture of the first housing member 702. For example, as particularly shown in cut-away side view in FIG. 7A, an angled slide component 741 can be slidably disassembled, for initiating disassembly of the inner core mold assembly. In an initial sequence, the angled slide component 741 can be removed from the interior cavity, through the major aperture of the first housing member 702. A notional arrow head shows direction of the angled slide component 741 of the inner core mold assembly sliding outwardly from the interior cavity, through the major aperture of the first housing member 702.

As shown in FIG. 7A, removal of the angled slide component 741 can free a first remaining component 742A of the inner core mold assembly, for lateral sliding within the interior cavity, towards the major aperture of the first housing member 702. A notional arrow head shows lateral direction of the first remaining component 742A of the inner core mold assembly, sliding laterally within the interior cavity, towards the major aperture of the first housing member 702.

As shown in cut-away bottom view in FIG. 7B, in addition to angled slide component 741 and first remaining component 742A (just discussed with respect to FIG. 7A), second remaining component 742B, and third remaining component 742C can be likewise slidably disassembled, for disassembling the inner core mold assembly. In FIG. 7B notional arrow head shows lateral direction of the first remaining component 742A of the inner core mold assembly, sliding laterally within the interior cavity, towards the major aperture of the first housing member 702. Additional notional arrow heads show central directions of central sliding of second remaining component 742B, and third remaining component 742C. After angled slide component 741 and first remaining component 742A are removed from the interior cavity, through the major aperture of the first housing member 702, second and third remaining components 742B, 742C can likewise be removed from the interior cavity, through the major aperture of the first housing member 702.

As shown in side view in FIG. 7B, first housing member 702 can be demolded from first and second mated plates 730A, 730B by separating first and second mated plates 730A, 730B along parting directions. First housing member 702 can be demolded from fixture 754.

In general, the steps associated with the methods of the present invention may vary widely. Steps may be added, removed, altered, combined, and reordered without departing from the spirit or the scope of the present invention.

The various aspects, features, embodiments or implementations of the invention described above may be used alone or in various combinations.

While this specification contains many specifics, these should not be construed as limitations on the scope of the disclosure or of what may be claimed, but rather as descriptions of features specific to particular embodiment of the disclosure. Certain features that are described in the context of separate embodiments may also be implemented in combination. Conversely, various features that are described in the context of a single embodiment may also be implemented in multiple embodiments separately or in any suitable subcombination. Moreover, although features may be described above as acting in certain combinations, one or more features from a claimed combination can in some cases be excised from the combination, and the claimed combination may be directed to a subcombination or variation of a subcombination.

The advantages of the invention are numerous. Different aspects, embodiments or implementations may yield one or more of the following advantages. One advantage may be increased strength from: a) an exterior surface of the first housing member covering a majority of the housing, b) the first housing member being of unitary construction, c) the first housing member being seamlessly constructed, and/or d) the first housing member being formed in one injection molding. Another advantage may be strength and/or efficiency in using an electrical power conduction pin for securing the cover plate to the first housing member.

The many features and advantages of the present invention are apparent from the written description and, thus, it is intended by the appended claims to cover all such features and advantages of the invention. Further, since numerous modifications and changes will readily occur to those skilled in the art, the invention should not be limited to the exact construction and operation as illustrated and described. Hence, all suitable modifications and equivalents may be resorted to as falling within the scope of the invention.

What is claimed is:

1. A housing for electronic components comprising:
a first housing member having a major interior surface that defines an interior cavity for receiving the electronic components;
a major aperture of the first housing member extending from the interior cavity through the first housing member to an exterior surface of the first housing member;
a cover plate for engaging the major aperture of the first housing member; and
an electrical power conduction pin extending through an aperture in the cover plate and arranged for mechanically coupling the cover plate with the major interior surface of the first housing member, so as to secure the cover plate to the first housing member.

2. A housing as recited in claim 1 wherein the first housing member is of unitary construction.

3. A housing as recited in claim 1 wherein the first housing member is seamlessly constructed.

4. A housing as recited in claim 1 wherein the first housing member is formed in one injection molding.

5. A housing as recited in claim 1 wherein:
the exterior surface of the first housing member covers a majority of the housing; and
an exterior surface of the cover plate substantially covers a minority remainder of the housing.

6. A housing as recited in claim 1 wherein the first housing member sufficiently encompasses the interior cavity for substantially occluding viewing of the major interior surface through the major aperture.

7. A housing as recited in claim 1 wherein the cover plate has a substantially L-shaped cross section.

8. A housing as recited in claim 1 wherein the major aperture of the first housing member has a substantially L-shaped cross section.

9. A housing as recited in claim 1 wherein:
the major aperture of the first housing member has an interior perimeter adjacent to the exterior surface of the first housing member;
the cover plate has an exterior perimeter; and
at least a portion of the exterior perimeter of the cover plate engages at least a portion of the interior perimeter of the major aperture of the first housing member.

10. A housing as recited in claim 9 wherein the interior perimeter of the major aperture has a reflex edge region for engaging the cover plate.

11. A housing as recited in claim 10 wherein the exterior perimeter of the cover plate has a mating reflex edge region for engaging the reflex edge region of the interior perimeter of the major aperture.

12. A housing as recited in claim 1 wherein:
the cover plate is substantially resilient; and
flexed insertion of the cover plate into the major aperture of the first housing member exerts a restoring force of the cover plate against the major aperture, for retaining the cover plate within the major aperture of the first housing member.

13. A housing as recited in claim 1 wherein:
the cover plate is substantially resilient; and
the cover plate has a substantially L-shaped cross section defining substantially orthogonal leg portions, so that upon flexed insertion of the cover plate into the major aperture of the first housing member, the substantially orthogonal leg portions are flexed towards each other.

14. A housing as recited in claim 1 wherein:
the electrical power conduction pin has a threaded extremity; and
the housing further comprises a threaded insert member for receiving the threaded extremity of the electrical power conduction pin, wherein the threaded insert member is mechanically coupled with the major interior surface of the first housing member.

15. A housing as recited in claim 14 wherein:
the first housing member comprises injection molded plastic; and
the threaded insert member is over-molded with the major interior surface of the first housing member for retaining the threaded insert member.

16. A housing as recited in claim 14 wherein the threaded insert member is heat staked to the major interior surface of the first housing member for retaining the threaded insert member.

17. A housing as recited in claim 14 wherein the threaded insert member is glued to the major interior surface of the first housing member for retaining the threaded insert member.

18. A housing as recited in claim 14 wherein the threaded insert member is ultrasonically welded to the major interior surface of the first housing member for retaining the threaded insert member.

19. A method for assembling a housing for electronic components comprising:
providing a first housing member having a major interior surface that defines an interior cavity for receiving the electronic components
providing a major aperture of the first housing member, extending through the first housing member from an exterior surface of the first housing to the interior cavity of the first housing member;
providing a cover plate for engaging the major aperture of the first housing member;
mechanically coupling a threaded insert member with the interior surface of the first housing member;
extending a threaded extremity of an electrical power conduction pin through an aperture in the cover plate; and
engaging the threaded insert member with a threaded extremity of the electrical power conduction pin for securing the cover plate to the first housing member.

20. A method as recited in claim 19 wherein mechanically coupling the threaded insert member with the interior surface of the first housing member comprises overmolding the threaded insert member with the interior surface of the first housing member.

21. A method as recited in claim 19 wherein mechanically coupling the threaded insert member with the interior surface of the first housing member comprises heat staking the threaded insert member to the interior surface of the first housing member.

22. A method as recited in claim 19 wherein mechanically coupling the threaded insert member with the interior surface of the first housing member comprises gluing the threaded insert member to the interior surface of the first housing member.

23. A method as recited in claim 19 wherein mechanically coupling the threaded insert member with the interior surface of the first housing member comprises ultrasonically welding the threaded insert member to the interior surface of the first housing member.

24. A method as recited in claim 19 wherein the first housing member sufficiently encompasses the interior cavity for substantially occluding viewing of the major interior surface through the major aperture

25. A method of molding a housing comprising:
providing an inner core mold assembly having a plurality of selectively moveable components, wherein the inner core mold assembly has an outer surface;
molding a major interior surface that defines an interior cavity of the housing over a portion of the outer surface of the inner core mold assembly; and
molding a major aperture of the housing over an extremity of the inner core mold assembly, so that the major aperture extends through the housing from the interior cavity of the housing, wherein molding the major interior surface sufficiently encompasses the interior cavity for the housing substantially occluding viewing of the major interior surface through the major aperture.

26. A method of molding a housing as recited in claim 25 further comprising:
slidably disassembling the plurality of selectively moveable components of the inner core mold assembly; and
sequentially removing each of the plurality of selectively moveable components of the inner core mold assembly from the interior cavity, through the major aperture of the housing.

27. A method of molding a housing as recited in claim 25 further comprising:
providing first and second mated plates having an inner surface for defining an outer surface of a mold cavity;
disposing the inner core mold assembly within the mold cavity;
forming an exterior surface of housing by molding the exterior surface of the housing to the outer surface of the mold cavity; and
demolding the housing from the first and second mated plates by separating the first and second mated plates along a parting direction.
